(19) United States
(12) Patent Application Publication
(10) Pub. No.: US 2008/0315354 A1
(43) Pub. Date: Dec. 25, 2008

(54) FUSE FOR SEMICONDUCTOR DEVICE

(76) Inventor: Jung-Ho Ahn, Danyang-gun (KR)

Correspondence Address: SHERR & VAUGHN, PLLC, 620 HERNDON PARKWAY, SUITE 200, HERNDON, VA, 20170, US

(21) Appl. No.: 12/142,913

(22) Filed: Jun. 20, 2008

(30) Foreign Application Priority Data
Jun. 25, 2007 (KR) 10-2007-0061964

(51) Int. Cl. H01L 29/00; H01L 21/44

(52) U.S. Cl. 257/529; 438/601; 257/E21.476; 257/E29.001

(57) ABSTRACT

Embodiments relate to a fuse for a semiconductor device. To maintain a stable blowing characteristic with a minimized applied current, the fuse includes a fuse line having a blowing characteristic dependent on applied current. A first contact pad has a plurality of contacts connected to one side of the fuse line. A second contact pad has a plurality of contacts connected to the other side of the fuse line. The first and second contact pads have an asymmetrical configuration, which may have different ratios of length to width.

The present application claims priority under 35 U.S.C. 119 to Korean Patent Application No. 10-2007-0061964 (filed on Jun. 25, 2007), which is hereby incorporated by reference in its entirety.

### BACKGROUND

Although a device may have only one defective cell among a large number of non-defective cells constituting a semiconductor device or a memory device, the device may not function properly. It may be considered a defective item overall. However, yield may be improved by replacing a defective cell using a preinstalled spare cell.

When a defective cell is identified by a test after completing wafer processing, a program changing an address corresponding to the defective cell to an address signal of a spare cell is applied to a semiconductor circuit. A fuse connected to a defective line may be blown. The connection is then changed to a spare line. To accomplish this, for example, the fuse may be burned out with a laser beam.

In a related process, when fabricating a logic circuit requiring a sophisticated resistor, it may be difficult to fabricate a resistor with a required resistance value within a particular process environment. To circumvent this difficulty, a fuse blowing technology may also be used. The sophisticated resistor may be implemented by connecting a plurality of fuses and then blowing a portion of the fuses to arrive at a required resistance value.

Therefore, the fuse blowing technology allows improvements in the efficiency of semiconductor design and modifications of chip function by rearrangement of circuits.

In the laser beam fuse blowing scheme, process conditions are troublesome. It is sophisticated work performed using separate laser equipment. The thickness of an oxide film on the fuse needs to be carefully controlled. For these reasons, an electrical fuse blowing method may be used. A current above a reference value is applied to the fuse to allow a desired connection portion to be selectively blown.

To use the electrical blowing method, pads are formed for electrical connections between semiconductor circuits. A plurality of electrical fuses (e-fuses) are connected between the pads. To blow the desired connection portion of the fuse, a predetermined bias voltage may be directly applied to a corresponding pad, according to a circuit changing program. A fuse satisfying electrical standards, with stable blowing characteristics, and resistance to electrical and thermal stresses is required.

### SUMMARY

Embodiments relate to a semiconductor device, and in particular relate to a fuse for a semiconductor device with stable blowing characteristics that minimize the applied electrical current. Embodiments relate to a fuse for a semiconductor device which includes a fuse line having a blowing characteristic dependent on applied current. A first contact pad has a plurality of contacts connected to one side of the fuse line. A second contact pad has a plurality of contacts connected to the other side of the fuse line. The first and second contact pads have an asymmetrical configuration, which may have different ratios of length to width.

The first and second contact pads may have a width wider than that of the fuse line. The ratio of a length to a width of the fuse line may be between approximately 3.7 to 4.0. The fuse line may be made of a polysilicon material, and blown with an applied current of about 1500 μA to 2500 μA.

The first and second contact pads may be formed as polygons having differing numbers of sides. For example, the first contact pad may have five sides and the second pad may have a rectangular shape. The number of contacts in the first contact pad and the number of contacts in the second contact pad may be unequal.

### DRAWINGS

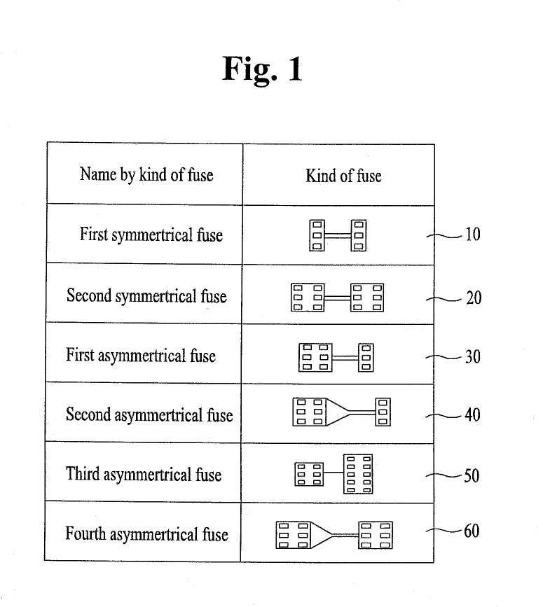

Example FIG. 1 illustrates various kinds of fuses used to search for an optimal shape and size of a fuse according to embodiments.

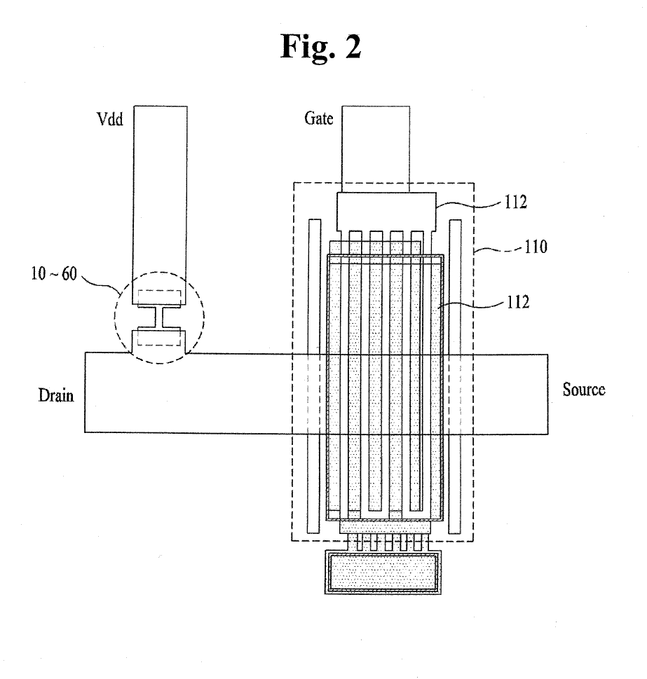

Example FIG. 2 illustrates the form of the fuses installed in a test apparatus for the test according to embodiments.

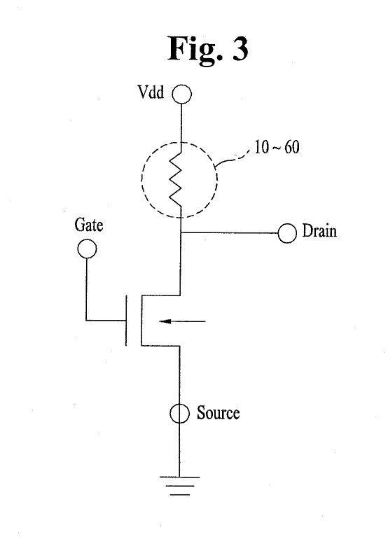

Example FIG. 3 illustrates a circuit equivalent of the fuses installed in a test apparatus for the test according to embodiments.

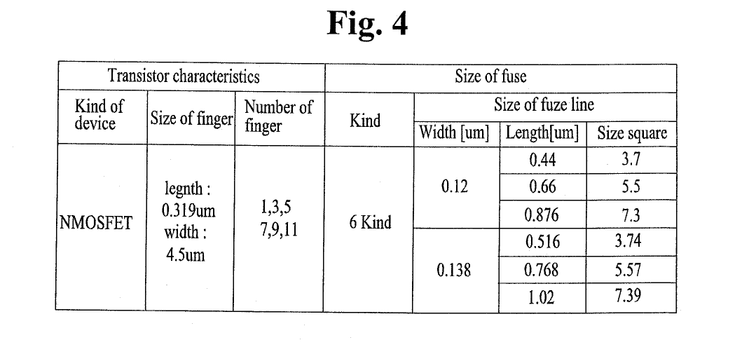

Example FIG. 4 illustrates characteristics of driving transistors and sizes of the fuses for the test according to embodiments.

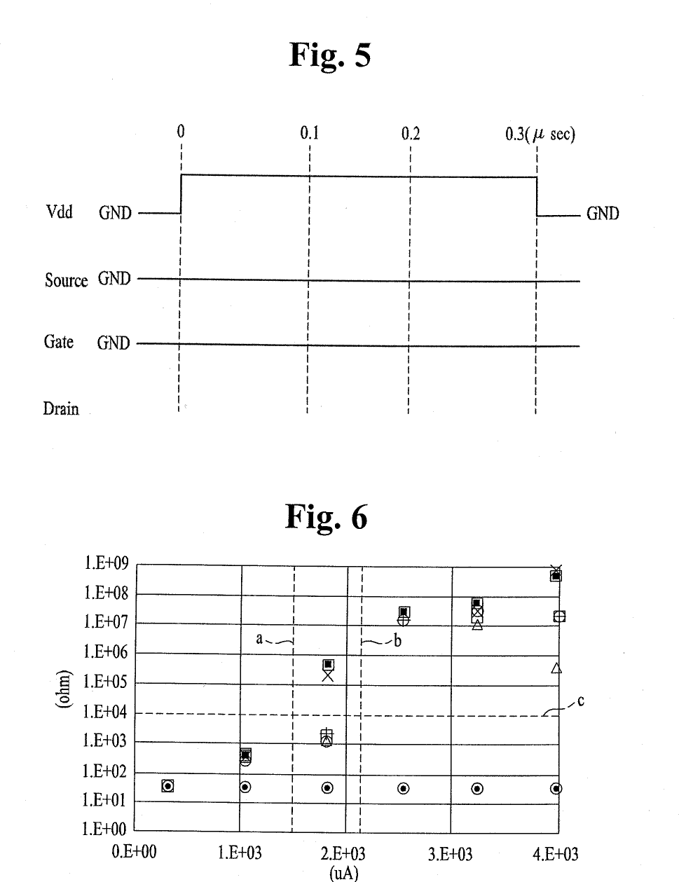

Example FIG. 5 is a graph measuring current applied to the test apparatus.

Example FIG. 6 is a graph measuring resistance values of the fuses with respect to applied current where the size of the fuses is about 3.7.

Example FIG. 7 is a graph measuring resistance values of the fuses with respect to current where the size of the fuses is about 5.5.

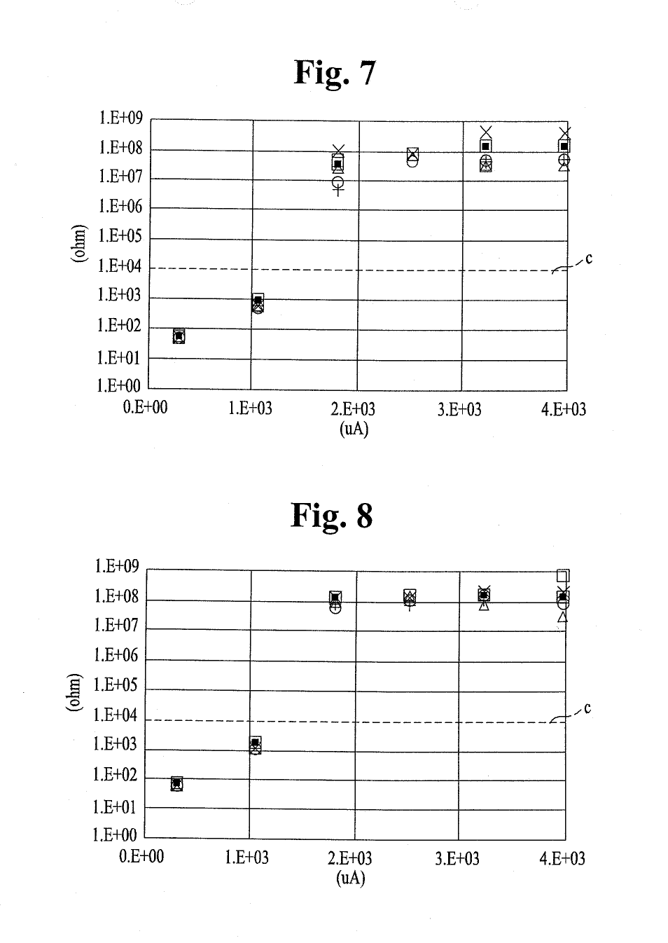

Example FIG. 8 is a graph measuring resistance values of the fuses with respect to current where the size of the fuses is about 7.3.

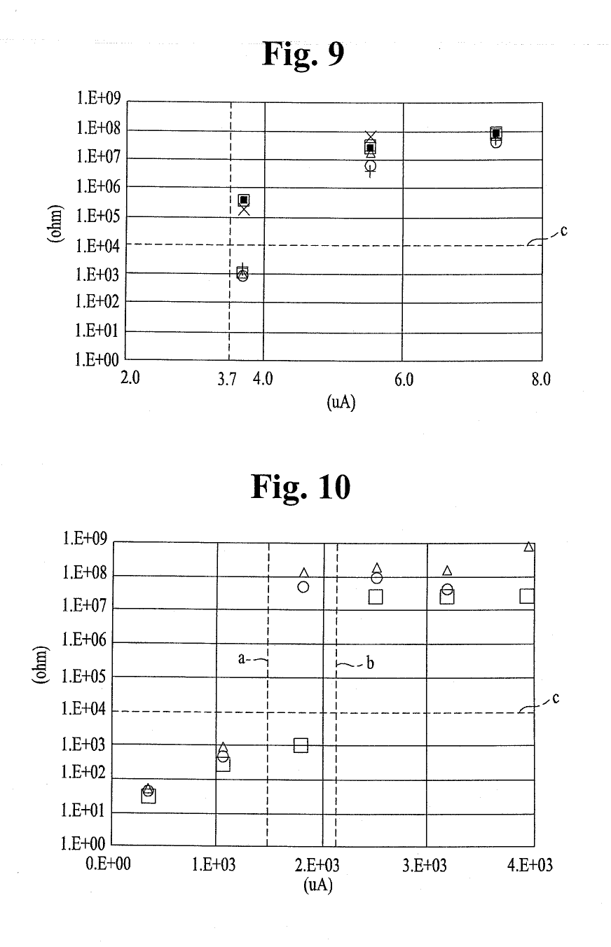

Example FIG. 9 is a graph measuring resistance values with respect to the size of the fuses where current of about 2000 μA is applied.

Example FIG. 10 is a graph of measured resistance values versus current of a first symmetrical fuse.

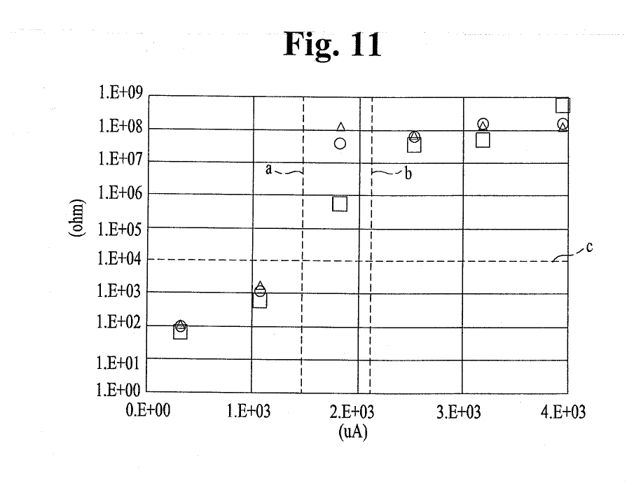

Example FIG. 11 is a graph measuring resistance values versus current of a fourth symmetrical fuse.

### DESCRIPTION

Hereinafter, a fuse for a semiconductor device according to embodiments will be described in detail with reference to accompanying drawings. The fuse for the semiconductor device according to embodiments is improved in shape and/or size so that it maximizes a stable blowing characteristic with a minimized applied current.

The optimal shape and/or size of the fuse for the semiconductor device are not derived with a theory or a mathematical principle, but may be obtained by testing fuses having various shapes and sizes under several conditions. Therefore, test conditions, processes, and analysis of test results of fuses for a semiconductor device will be described with reference to accompanying drawings.

Example FIG. 1 illustrates various kinds of fuses used to search for an optimal shape and size of a fuse according to embodiments.

Referring to example FIG. 1, fuses for a semiconductor device, used as examples for testing, may be divided into six kinds of fuses. Example FIG. 1 illustrates a first symmetrical fuse 10, a second symmetrical fuse 20, a first asymmetrical fuse 30, a second asymmetrical fuse 40, a third asymmetrical fuse 50, and a fourth asymmetrical fuse 60. Fuses 10 to 60 for the test according to embodiments may be constituted by two contact pads which may be connected to a substrate pad when they are mounted in a substrate. A fuse line connects between the contact pads, and may be blown when an over-current is applied.

The contact pads may be wider than the fuse line, and may include a plurality of contacts therein to improve conductivity to a circuit pad formed on the substrate. The size, shape, and number of the contact pads are included in test conditions. The test conditions may become references through which the fuses for the test are divided into symmetrical fuses and asymmetrical fuses.

The two contact pads for the first symmetrical fuse 10 have a rectangular shape and are the same size. The second symmetrical fuse 20 has a symmetrical structure similar to the first symmetrical fuse 10, however, the contact pads are a different size. Three contacts are included in the inside of the contact pad for the first symmetrical fuse 10 and six contacts are included in the inside of the contact pad for the second symmetrical fuse 20. Therefore, the contact pad for the second symmetrical fuse 20 is larger than the contact pad for the first symmetrical fuse 10.

The contact pad on one side of the first asymmetrical fuse 30 may have three contacts and the contact pad on the other side may have six contacts. The sizes of the contact pads are different so that the first asymmetrical fuse has an asymmetrical structure.

The contact pad on one side of the third asymmetrical fuse 50 has six contacts and the contact pad on the other side has ten contacts. Therefore, the sizes of the contact pads are different so that the third asymmetrical fuse has an asymmetrical structure. Thus, all of the contact pads for the first asymmetrical fuse 30 and the third asymmetrical fuse 50 have a rectangular shape.

The contact pad on one side of the second asymmetrical fuse 40 and the fourth asymmetrical fuse 60 and the contact pad on the other side are different in both shape and size so that the second asymmetrical fuse 40 and the fourth asymmetrical fuse 60 have asymmetrical structures. The contact pad on one side of the second asymmetrical fuse 40 includes a pad portion with a triangular shape and the contact pad on the other side has a rectangular shape. Likewise, the contact pad on one side of fourth asymmetrical fuse 60 includes a pad portion with a triangular shape and the contact pad on the other side has a rectangular shape. The contact pads having the triangular portion have a rectangular portion joined to the triangular portion. The triangular portion has a first side coterminal with a side of the rectangular portion. A vertex of the triangle opposite the first side of the triangle connects to an end of the fuse line. The scope of embodiments are not limited to this form of main body (the rectangular portion) and taper (the triangular portion).

The contact pad on one side of the second asymmetrical fuse 40 includes six contacts and the contact pad on the other side includes three contacts. Both contact pads on the fourth asymmetrical fuse 60 include six contacts. Although other types and a much greater number of fuses than the above-mentioned examples have been tested, only the six kinds of fuses for the test having substantial differences in the resulting analysis will be briefly described.

Example FIG. 2 illustrates schematically the fuses 10 to 60 installed in a test apparatus according to embodiments. Example FIG. 3 illustrates a circuit equivalent of the fuses installed in a test apparatus for the test according to embodiments.

As shown in example FIG. 2, the test apparatus includes a driving transistor 110 capable of supplying various currents to the fuses 10 to 60 for the test. The driving transistor 110 may be provided as, for example, an N-channel metal-oxide field-effect transistor (NMOSFET). The contact pad on one side of the contact pads for the fuses 10 to 60 is connected to a power supply terminal Vdd and the contact pad on the other side is connected to a drain terminal of the driving transistor 110. A source terminal of the driving transistor 110 is used as a ground terminal and a gate terminal thereof is used as a control terminal. The driving transistor 110 includes a poly gate region 112 shaped like a plurality of fingers, and an active region on a substrate. Controlling the number of fingers in the driving transistor 110 can control the amount of current applied to the fuses 10 to 60 for the test.

Referring to example FIG. 3, a circuit equivalent to the fuse test apparatus constituted by the fuses 10 to 60 for the test of a resistance component and the driving transistor 110 is shown. A drain line of the driving transistor 110 is connected to the fuses 10 to 60 for the test, and a source line thereof is used as a ground terminal Vss. When a control signal is input through a gate line, the driving transistor 110 operates and current is applied to the fuse 10 to 60 for the test.

Example FIG. 4 illustrates characteristics of driving transistors and sizes of the fuses 10 to 60 for the test according to embodiments. Referring to example FIG. 4, test conditions will be described. Fuses 10 to 60 are polysilicon electrical fuses (e-fuses) and may be fabricated through a CMOS process. Fuses 10 to 60 may be divided into the six kinds of fuses according to the shape and size of the pad as described in example FIG. 1. Fuses 10 to 60 may again be subdivided into six sorts of fuses according to the size of a fuse line.

The width of the fuse line has been varied within a range of about 0.12 μm to 0.14 μm, and the length thereof has been varied within a range of about 0.44 μm to 1.02 μm. The thickness of the fuse line may be held constant at about 1840 Å. The thickness is not varied in the test conditions because it has a very small effect on the current.

The size of the fuse line is set for the test, and a blowing characteristic according to a current value may be generalized according to the “size square” determined by the length and the width of the fuse line. The size square of the length and the width of the fuse line may be represented as a value dividing the length by the width, and the fuse for the test has a value of about 2.0 to 8.0 (see the X-axis in example FIG. 9). Therefore, the size of the fuse line will be referred to as the size square of the length and the width. The size of the fuse line will be used as the size of the fuse for the test.

Many more fuse lines with various values besides those shown in example FIG. 4 have been tested in the fuse test performed according to embodiments. Only six kinds, of sizes 3.7, 3.74, 5.5, 5.57, 7.3, and 7.39, which have substantial differences in the resulting analysis will be described.

The driving transistor 110 may be a multi-finger type to apply various currents as described above, wherein the number of the fingers may be 1, 3, 5, 7, 9, and 11. All of the fingers of the driving transistor 110 may have a length of about 0.319 μm and a width of about 4.5 μm. Therefore, since the total width (4.5 μm×3) of the fingers in the case where there are three fingers becomes threefold compared to the case where there is one finger (4.5 μm), the current also increases threefold. Accordingly, the current transferred to the fuses 10 to 60 for the test may be controlled.

Example FIG. 5 is a graph measuring current applied to the test apparatus. Referring to example FIG. 5, a test process according to an embodiment will be described. When the fuse is installed in the test apparatus, a voltage of approximately 3.3 V is applied to a power supply terminal Vdd for approximately 0.3 μsec. After 3.3 V is applied to the power supply terminal, a control voltage of approximately 3.3 V is applied to the gate terminal of the driving transistor 110 for approximately 0.1 to 0.2 μsec. The source terminal is maintained in a ground state of 0 V. Thus, a channel of the transistor 110 is opened during simultaneous application of the operational voltage and the control voltage, and the maximum current capable of flowing through the transistor 110 may be supplied to the fuses 10 to 60 for the test. A 50 mV signal may be applied to the power supply terminal Vdd to measure resistance between the power supply terminal Vdd and the drain.

The resistances depend on the contact pad of the fuses 10 to 60 for the test, the size of the fuse line, and the kind of applied current at the time of test. For reference, the kind of applied current may be interpreted as meaning the kind of driving transistor. Hereinafter, an analysis of test results of the fuses will be described.

Example FIG. 6 is a graph measuring resistance values of the fuses 10 to 60 with respect to applied current in the case where the size of the fuses is about 3.7. Example FIG. 7 is a graph measuring resistance values of the fuses 10 to 60 with respect to current where the size of the fuses is about 5.5. Example FIG. 8 is a graph measuring resistance values of the fuses 10 to 60 with respect to current where the size of the fuses is about 7.3. Example FIG. 9 is a graph measuring resistance values with respect to the size of the fuses 10 to 60 where current of about 2000 μA is applied.

In example FIGS. 6 to 8, the X axis represents current in μA applied to the fuses 10 to 60. The Y axis represents a measured resistance value Ω of the fuses 10 to 60 after the test. “1.E+03” on the Y axis indicates “10³”. In the measuring graphs (example FIGS. 6 to 9), a symbol “□” indicates a measured value of the first symmetrical fuse 10, and symbols “∘”, “Δ”, “×”, “+”, and “ [symbol] ” indicate measured values of the second symmetrical fuse 20, the first asymmetrical fuse 30, the second asymmetrical fuse 40, the third asymmetrical fuse 50, and the fourth asymmetrical fuse 60, respectively. The symbol “⊙” indicates an initial resistance number of the fuses 10 to 60 for the test. Six points at which the symbols are marked are on the basis of current differentiated according to the number (1, 3, 5, 7, 9, 11) of the fingers of the driving transistor 110.

Referring to example FIG. 6, the resistance values of the fuses 10 to 60 after the application of the current have been measured to be higher than initial resistance values, that is, resistance values in a state where the current has not been applied. Using about 1400 ohm (c) on the X axis as a reference, if the resistance value of the fuse after the test is higher than the reference (c), it may be interpreted that the fuse is blown and if it is lower than the 140 ohm (c), it may be interpreted that the fuse is not yet blown.

When interpreting the graph of example FIG. 6 by applying such a reference, in the case where current below about 1500 μA (a) is applied, all of the six kinds of fuses 10 to 60 for the test are not blown, and in the case where current between about 1500 μA (a) to 2500 μA (b) is applied, a difference between the fuses 10 to 60 for the test occurs.

Where a current between 1500 μA (a) and 2500 μA (b) is applied, the second asymmetrical fuse 40 and the fourth asymmetrical fuse 60 are blown and remaining kinds of fuses 10, 20, 30, and 50 for the test are not blown. Where current above 2500 μA (b) is applied, all of the six kinds of fuses 10 to 60 for the test are blown. Therefore, it may be appreciated that only the second asymmetrical fuse 40 and the fourth asymmetrical fuse 60 have a blowing characteristic differentiated from other kinds of fuses 10, 20, 30, and 50 for the test within a proper current range (a to b).

As shown in example FIGS. 7 and 8, when comparing the measured resistance values where the size of the fuses 10 to 60 is varies from about 5.5 to about 7.3, it may be appreciated that all of the six kinds of fuses 10 to 60 have similar blowing characteristics irrespective of the applied current. In other words, if the size of the fuses 10 to 60 become larger than a predetermined value, a differentiation by shape among the kinds of fuses (refer to example FIG. 1) and the kinds (or values) of applied current does not exist.

According to the results of the above analysis, it may be appreciated that in order to improve the size and the shape of the fuse so that the fuse has a stable blowing characteristic with a minimized applied current, the size of the fuses should be in a predetermined range, with a predetermined current range. The predetermined range of current is between about 1500 μA (a) to 2500 μA(b).

Hereinafter, referring to example FIG. 9, the predetermined range of the size of the fuses will be analyzed. In example FIG. 9, the X axis represents the size (size square—the length divided by the width) of the fuses 10 to 60, and the Y axis represents the measured resistance value Ω of the fuses after the test.

As analyzed in example FIG. 6, where current between about 1500 μA (a) to 2500 μA(b) is applied and the size of the fuse is 3.7, only the second asymmetrical fuse 40 and the fourth asymmetrical fuse 60 indicate the blowing characteristic. The blowing characteristic as differentiated according to the size of the fuse may be appreciated by example FIG. 9.

Referring to example FIG. 9, where a current of about 2000 μA is applied and the size of the fuse is about 3.7 to 4.0, only the second asymmetrical fuse 40 and the fourth asymmetrical fuse 60 are blown. If the size of the fuse is smaller than 3.7, all six kinds of fuses 10 to 60 are not blown. If the size of the fuse is larger than 4.0, all six kinds of fuses 10 to 60 are blown. Therefore, the predetermined range of the size of the fuse may be defined as about 3.7 to 4.0.

Example FIG. 10 is a graph measuring resistance value versus current of the first symmetrical fuse 10, and example FIG. 11 is a graph measuring resistance values versus current of a fourth symmetrical fuse 60. In example FIGS. 10 and 11, the symbol “□” indicates a measured value where the sizes of the first symmetrical fuse 10 and the fourth asymmetrical fuse 40 are 3.7, and symbols “∘” and “Δ” indicates measured values where the sizes of the first symmetrical fuse 10 and the fourth asymmetrical fuse 40 are 5.5 and 7.3, respectively.

Referring to example FIG. 10, where a current below about 1500 μA (a) is applied, all of the first symmetrical fuses 10 of the three sizes are not blown. Where a current above 2500 μA (b) is applied, all of the first symmetrical fuses of the three sizes are blown. Where a current between 1500 μA (a) to 2500 μA (b) is applied, the first symmetrical fuse 10 of the size of 3.7 is not blown, however, the first symmetrical fuses 10 of the sizes of 5.5 and 7.3 are blown. Thus, the first symmetrical fuse 10 does not indicate a stable blowing characteristic according to size.

Referring to example FIG. 11, where a current below about 1500 μA (a) is applied, all of the fourth asymmetrical fuses 60 of the three sizes are not blown. Where a current above 1500 μA (b) is applied, all of the fourth asymmetrical fuses of the three sizes are blown. Thus, the fourth fuse 60 manifests the same blowing characteristic irrespective of size. Therefore, if an asymmetrical fuse is used, the blowing characteristics do not vary with size, so that flexibility of a circuit design may be secured.

According to the analysis of the fuse for the test as above, it is possible to derive following conclusions. First, an asymmetrical fuse for a semiconductor device may have a consistent blowing characteristic. In particular, where the sizes and shapes of the contact pads are different, for example, in the case of the second asymmetrical fuse 40 and the fourth asymmetrical fuse 60, the consistency of the blowing characteristic is improved. Second, only an applied current of about 1500 μA (a) to 2500 μA (b) distinguishes the fuse with an excellent blowing characteristic among various kinds of contact pads and sizes of fuse lines. Third, in the above current application range, only the second asymmetrical fuse 40 and the fourth asymmetrical fuse 60, with a size square of 3.7 to 4.0 have a stable blowing characteristic.

According to these conclusions, a fuse for a semiconductor device according to embodiments has a length to width ratio of 3.7 to 4.7. The fuse is fabricated so that the shapes and sizes of the contact pads are different, to provide an optimal blowing characteristic for currents of 1500 μA (a) to 2500 μA (b). The size of the fuse or the contact pad in the above description means the size square of the length divided by the width of them, for example, square=length/width.

According to embodiments, it is possible to fabricate a fuse for a semiconductor device capable of simultaneously satisfying a minimum applied current reference and a maximum applied current reference while maintaining a consistent blowing characteristic. It is possible to provide design modifications of the semiconductor devices with flexibility and ease, and reduce the time and cost required.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a fuse line having a blowing characteristic dependent on an applied current;
a first contact pad having a plurality of contacts connected to one side of the fuse line; and
a second contact pad having a plurality of contacts connected to the other side of the fuse line,
wherein the first and second contact pads have an asymmetrical configuration.

2. The apparatus of claim 1, wherein the first and second contact pads have a width wider than that of the fuse line.

3. The apparatus of claim 1, wherein the ratio of a length to a width of the fuse line is about 3.7 to 4.0.

4. The apparatus of claim 1, wherein the fuse line is blown with an applied current of about 1500 μA to 2500 μA.

5. The apparatus of claim 1, wherein the fuse line is made of a polysilicon material.

6. The apparatus of claim 1, wherein the first and second contact pads have an asymmetrical configuration with different ratios of length to width.

7. The apparatus of claim 1, wherein the first and second contact pads are formed in an asymmetrical configuration, substantially different in shape.

8. The apparatus of claim 7, wherein the first and second contact pads are formed as polygons having differing numbers of sides.

9. The apparatus of claim 7, wherein the first contact pad has five sides and the second pad has a rectangular shape.

10. The apparatus of claim 7, wherein the first contact pad has a rectangular portion joined to a triangular portion, wherein the triangular portion has a first side coterminal with a side of the rectangular portion, and wherein a vertex of the triangle opposite the first side of the triangle connects to an end of the fuse line.

11. The apparatus of claim 1, wherein the number of contacts in the first contact pad and the number of contacts in the second contact pad are unequal.

12. The apparatus of claim 1, wherein the fuse line is blown with an applied current of about 2000 μA.

13. The apparatus of claim 7, wherein the first contact pad has a main portion joined to tapered portion, and wherein the tapered portion has a first side coterminal with a side of the main portion, and a tapered end which connects to an end of the fuse line.

14. The apparatus of claim 10, wherein the second pad has a rectangular shape.

15. The apparatus of claim 13, wherein the second pad has a rectangular shape.

16. The apparatus of claim 15, wherein the rectangle is a square.

17. A method comprising:
forming a fuse line having a blowing characteristic dependent on applied current;
forming a first contact pad having a plurality of contacts connected to one side of the fuse line; and
forming a second contact pad having a plurality of contacts connected to the other side of the fuse line,
wherein the first and second contact pads have an asymmetrical configuration.

18. The method of claim 17, wherein the first and second contact pads are formed in an asymmetrical configuration, substantially different in shape.

19. The method of claim 17, wherein the first contact pad has a rectangular portion joined to a triangular portion, wherein the triangular portion has a first side coterminal with a side of the rectangular portion, and wherein a vertex of the triangle opposite the first side of the triangle connects to an end of the fuse line.

20. The method of claim 17, wherein the first contact pad has a main portion joined to tapered portion, and wherein the tapered portion has a first side coterminal with a side of the main portion, and a tapered end which connects to an end of the fuse line.
